(19) United States
(12) Patent Application Publication
(10) Pub. No.: US 2011/0006692 A1
(43) Pub. Date: Jan. 13, 2011

(54) APPARATUS FOR DRIVING CAPACITIVE LIGHT EMITTING DEVICE

(75) Inventors: Satoru Washiya, Saitama (JP); Toshihiro Ehara, Saitama (JP); Shohei Osaka, Saitama (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Sanken Electric Co., Ltd., Niiza-shi (JP)

(21) Appl. No.: 12/920,368

(22) PCT Filed: Mar. 5, 2009
(86) PCT No.: PCT/JP2009/054202

§ 371 Date: Aug. 31, 2010

(30) Foreign Application Priority Data
Mar. 26, 2008 (JP) 2008-082039

(51) Int. Cl. H05B 37/02

(52) U.S. Cl. 315/185 R; 315/291; 315/287

(57) ABSTRACT

A capacitive light emitting device includes: a capacitive light emitting device 1 placed between a cathode electrode and an anode electrode opposite to each other on a light-transmitting substrate; a power supply Vin connected to the capacitive light emitting device; drive means 10 for driving the capacitive light emitting device by applying a DC voltage of the power supply between the cathode electrode and the anode electrode; and regeneration means L2, Q3 for returning electric charges to the power supply for regeneration, the electric charges being accumulated in a parasitic capacitance of the capacitive light emitting device while the capacitive light emitting device is driven.

### APPARATUS FOR DRIVING CAPACITIVE LIGHT EMITTING DEVICE TECHNICAL FIELD

The present invention relates to an apparatus for driving a capacitive light emitting device, which is configured to drive a capacitive light emitting device having a large capacitive component like an organic EL (electroluminescence) device made of an organic substance and other light emitting devices.

### BACKGROUND ART

In the case of an LED (light emitting diode) exhibiting a current-voltage characteristic which is similar to that of the capacitive light emitting device, as shown in FIG. 1, dimming (control of luminance or brightness) is efficiently carried out by applying PWM (Pulse Width Modulation) control to a pulse signal by use of another pulse signal. In addition, a method similar to the pulse drive/dimming method for the LED shown in FIG. 1 is used as a pulse drive/dimming method for the capacitive light emitting device.

An organic material which is a material of the capacitive light emitting device has a higher dielectric constant than semiconductors and metals. It is easy to increase the area of the capacitive light emitting device. For this reason, the parasitic capacitance of the capacitive light emitting device tends to be extraordinarily larger than those of light emitting devices such as LEDs.

As a result, when the capacitive light emitting device is driven by pulses, a large amount of (−) electric charges accumulated in the parasitic capacitance of the capacitive light emitting device cannot be fully discharged during OFF period in the pulse driving. Accordingly, dielectric polarization remains in organic molecules around a light emitting layer of the capacitive light emitting device. This condition raises the temperature of a panel on which the capacitive light emitting device is mounted.

The life of the material of the capacitive light emitting device is very short when the capacitive light emitting device is operated at high temperature. The life becomes shorter due to even only heat generation accompanying light emission. For this reason, when driving the capacitive light emitting device by pulses, a conventional apparatus for driving a capacitive light emitting device resets (−) electric charges, which are accumulated in the parasitic capacitance of the capacitive light emitting device, for each cycle by applying a pulse signal having a reverse voltage VL, which is lower than a reverse breakdown voltage of the capacitive light emitting device, to the capacitive light emitting device as shown in FIG. 2. Thereby, the conventional apparatus prevents the temperature of the panel from rising due to the (−) electric charges accumulated therein, and achieves the extension of the life of the capacitive light emitting device (Japanese Patent No. 3169974 (FIGS. 1 and 2)).

### DISCLOSURE OF THE INVENTION

However, the conventional pulse drive shown in FIG. 2 needs two power supplies, which includes a dedicated negative power supply for applying the reverse voltage (reverse bias) to the capacitive light emitting device and a power supply for light emission, for the purpose of achieving the extension of the life of the capacitive light emitting device. In addition, the conventional pulse drive shown in FIG. 2 only applies the reverse voltage (reverse bias) to the capacitive light emitting device for the purpose of achieving the extension of the life of the capacitive light emitting device. For this reason, although the electric charges accumulated in the parasitic capacitance of the capacitive light emitting device are drawn out therefrom, none of the electric charges are returned to the power supply for light emission of the capacitive light emitting device for regeneration.

Because the capacitive light emitting device has characteristics such as the large dielectric constant organic material and the large area, most of an electric power inputted thereto is charged in the parasitic capacitance. After the charge is completed, the capacitive light emitting device starts its light emission. When the reverse bias is applied to the capacitive light emitting device for the purpose of extending the life of the capacitive light emitting device, all of the electric charges charged in the parasitic capacitance are discarded. If only the application of the reverse bias is carried out, the power efficiency remains very poor.

An object of the present invention is to provide an apparatus for driving a capacitive light emitting device which is capable of achieving the extension of the life and the reduction in the power consumption of the capacitive light emitting device.

To solve the above problem, a first invention includes: a capacitive light emitting device placed between a cathode electrode and an anode electrode opposite to each other on a light-transmitting substrate; a power supply connected to the capacitive light emitting device; drive means for driving the capacitive light emitting device by applying a DC voltage of the power supply between the cathode electrode and the anode electrode; and regeneration means for returning an electric charge to the power supply for regeneration, the electric charge being accumulated in a parasitic capacitance of the capacitive light emitting device while the capacitive light emitting device is driven.

A second invention includes: a capacitive light emitting device placed between a cathode electrode and an anode electrode opposite to each other on a light-transmitting substrate; a power supply connected to the capacitive light emitting device; drive means for driving the capacitive light emitting device by applying a DC voltage of the power supply between the cathode electrode and the anode electrode; and regeneration means being connected to the capacitive light emitting element, and including a reactor, a rectifier and a drive element. The regeneration means turns on the drive element to accumulate in the reactor an electric charge which is accumulated in a parasitic capacitance of the capacitive light emitting device while the capacitive light emitting device is driven; thereafter causes the rectifier to apply a reverse voltage, which is equal to or less than a reverse breakdown voltage of the capacitive light emitting device, to the capacitive light emitting device; and turns off the drive element to return the electric charge, which is accumulated in the reactor, to the power supply for regeneration.

In a third invention, the capacitive light emitting device is provided in plurality, and the plurality of capacitive light emitting devices are connected together in series or in parallel.

In a fourth invention, the capacitive light emitting device includes a plurality of light emitting layers made of organic substances placed between the cathode electrode and the anode electrode, the organic substances are laminated together by use of a separation layer having an electrical conductivity and a light transmitting property; and each or all of the plurality of separated light emitting layers emit light.

In a fifth invention, the drive means drives the capacitive light emitting element with a first pulse signal; and the control circuit turns on and off the drive element with a second pulse signal, one pulse of the second pulse signal being outputted per output of every two or more pulses of the first pulse signal.

### BRIEF DESCRIPTION OF THE DRAWINGS

FIG. 1 is a diagram showing an instance of a waveform of a pulse voltage which is applied to a capacitive light emitting device included in a conventional apparatus for driving a capacitive light emitting device.

FIG. 2 is a diagram showing another instance of the waveform of the pulse voltage which is applied to the capacitive light emitting device included in the conventional apparatus for driving a capacitive light emitting device.

FIG. 3 is a circuit diagram of an apparatus for driving a capacitive light emitting device according to Example 1.

FIG. 4 is a diagram showing a waveform of a pulse voltage which is applied to a capacitive light emitting device according to Example 1.

FIG. 5 is a diagram for explaining an operation which is performed by the apparatus for driving a capacitive light emitting device according to Example 1 in each mode.

FIG. 6 is a timing chart showing an operation which is performed by each part in the apparatus for driving a capacitive light emitting device according to Example 1 in a case where: a dead time occurs; and regeneration is carried out for each two pulses.

FIG. 7 is a timing chart showing an operation which is performed by each part in the apparatus for driving a capacitive light emitting device according to Example 1 in a case where a dead time occurs.

FIG. 8 is a timing chart showing an operation which is performed by each part in the apparatus for driving a capacitive light emitting device according to Example 1 in a case where no dead time occurs.

FIG. 9 is a circuit diagram of an apparatus for driving a capacitive light emitting device according to Example 2.

FIG. 10 is a circuit diagram of an apparatus for driving a capacitive light emitting device according to Example 3.

FIG. 11 is a diagram for explaining an operation which is performed by the apparatus for driving a capacitive light emitting device according to Example 3 in each mode.

FIG. 12 is a diagram of a basic structure for capacitive light emitting devices.

FIG. 13 is a diagram showing a first configuration example where multiple capacitive light emitting devices are connected together in series.

FIG. 14 is a diagram showing a second configuration example where the multiple capacitive light emitting devices are connected together in series.

FIG. 15 is a diagram of a structure of a capacitive light emitting device including multiple light emitting layers.

FIG. 16 is a diagram showing the first configuration example where the multiple capacitive light emitting devices are connected together in parallel instead.

FIG. 17 is a diagram showing the second configuration example where the multiple capacitive light emitting devices are connected together in parallel instead.

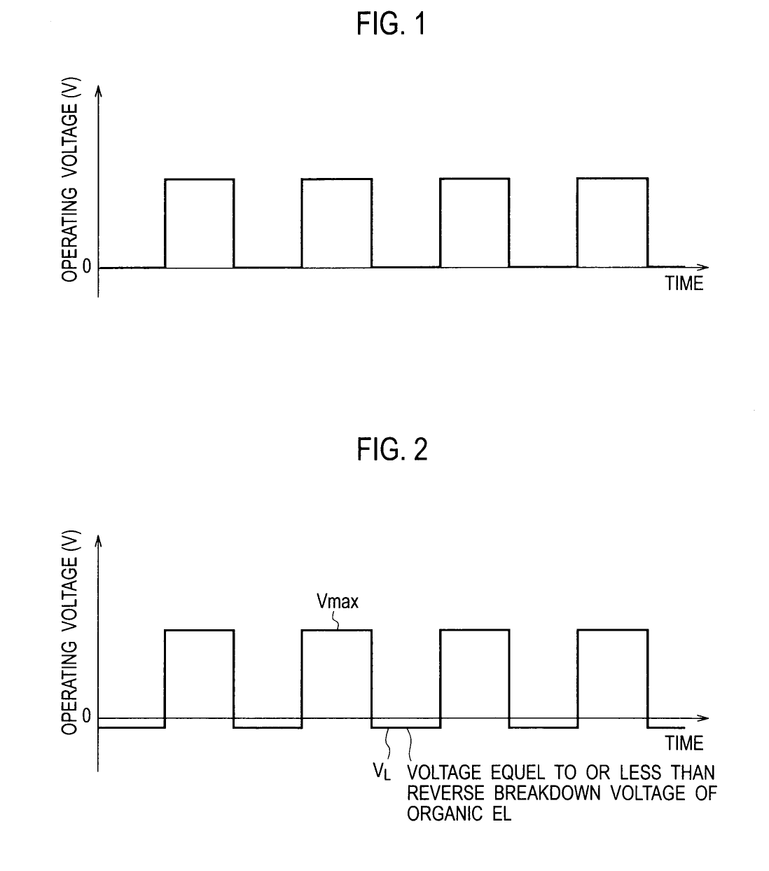

### BEST MODES FOR CARRYING OUT THE INVENTION

Detailed descriptions will be hereinbelow provided for embodiments of an apparatus for driving a capacitive light emitting device according to the present invention by referring to the drawings.

### Example 1

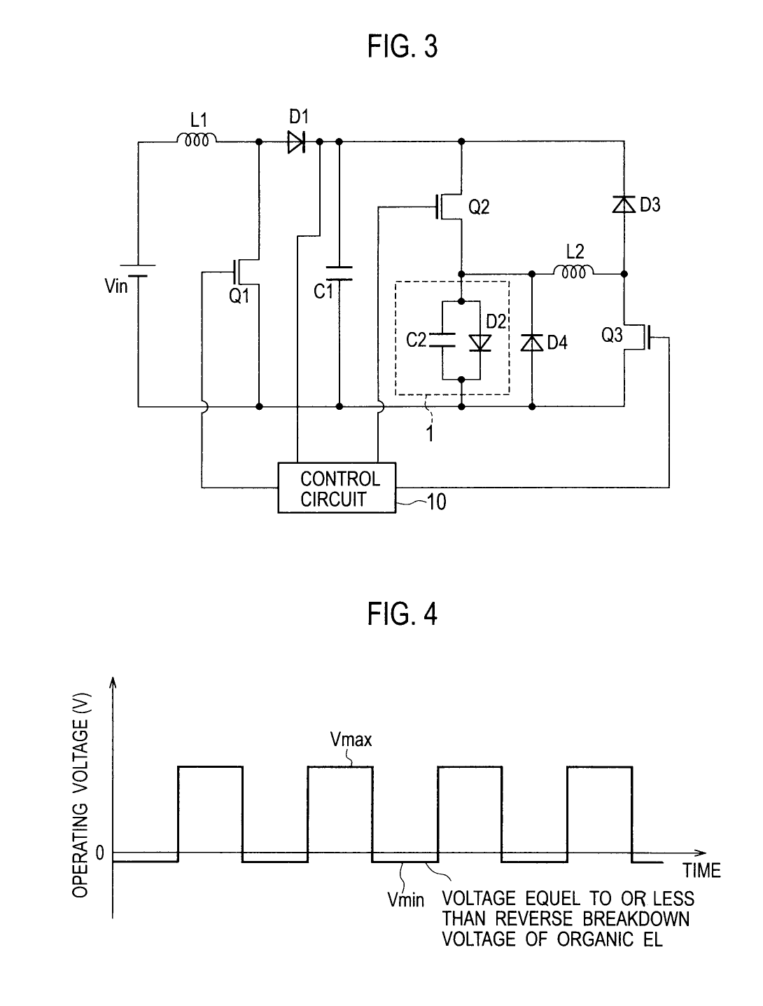

FIG. 3 is a circuit diagram of the apparatus for driving a capacitive light emitting device according to Example 1. The apparatus for driving a capacitive light emitting device according to Example 1 is configured in that: electric charges having been accumulated in the capacitive light emitting device are drawn out therefrom by applying a reverse bias voltage Vmin, which is equal to or less than a reverse breakdown voltage of the capacitive light emitting device, to the capacitive light emitting device as shown in FIG. 4; and the electric charges thus drawn-out are reused for light emission of the capacitive light emitting device after returned to the power supply for regeneration. This configuration makes it possible to extend the life of the capacitive light emitting device, and to use the electric power with high efficiency.

The capacitive light emitting device is a device which has a large capacitive component like organic EL devices each made of an organic substance and other light emitting devices.

In FIG. 3, a series circuit including a reactor L1 and a drive element Q1 made of a MOSFET is connected to the two ends of a DC power supply Vin. A series circuit including a diode D1 and a capacitor C1 is connected between the source and drain of the drive element Q1.

A series circuit including a drive element Q2 made of a MOSFET and a capacitive light emitting device 1 is connected to the two ends of the capacitor C1. The capacitive light emitting device 1 includes an organic EL layer made of an organic substance and placed between a cathode electrode and an anode electrode which are opposite to each other on a light-transmitting substrate. The capacitive light emitting device 1 is represented by an equivalent circuit consisting of a capacitor C2 and a diode D2. Note that details of the structure of the capacitive light emitting device 1 will be described later.

A series circuit including a diode D3 and a drive element Q3 (corresponding to the drive element according to the present invention) made of a MOSFET is connected to the two ends of the series circuit including the drive element Q2 and the capacitive light emitting device 1. A reactor L2 (corresponding to the reactor according to the present invention) is connected between two connecting points. One of the two connecting point is a connecting point between the drive element Q2 and the capacitive light emitting device 1. The other of the two connecting points is a connecting point between the diode D3 and the driving element Q3. A diode D4 (corresponding to the rectification element according to the present invention) is connected to the two ends of the capacitive light emitting device 1. A voltage reduced by a forward voltage drop of the diode D4 is equal to or less than the reverse breakdown voltage of the capacitive light emitting device 1.

The DC power supply Vin, the reactor L1, the drive element Q1, the diode D1 and the capacitor C1 constitute a boost chopper circuit. Note that a DC-DC converter may be used instead of the boost chopper circuit.

A control circuit 10 (corresponding to the drive means and control circuit according to the present invention) is connected to the gate of the drive element Q1, the connecting point between the diode D1 and the capacitor C1, the gate of the drive element Q2 and the gate of the drive element Q3. The control circuit 10 controls the on/off of the drive element Q1 with a first PWM control signal based on a voltage between the two ends of the capacitor C1. Thereby, the control circuit 10 makes control to make the voltage between the two ends of the capacitor C1 equal to a predetermined voltage.

In addition, the control circuit 10 controls the on/off of the drive element Q2 with a second PWM control signal. Thereby, the control circuit 10 controls the light emission of the capacitive light emitting device 1, and concurrently turns on and off the drive element Q2 and the drive element Q3 alternately.

Specifically, during a time period in which no voltage is applied between the cathode electrode and anode electrode of the capacitive light emitting device 1, the control circuit 10 turns on the drive element Q3, and thus accumulates electric charges, which are accumulated in the parasitic capacitance between the cathode electrode and anode electrode of the capacitive light emitting device 1, in the reactor L2. Subsequently, the control circuit 10 causes the diode D4 to apply a reverse voltage, which is equal to or less than the reverse breakdown voltage of the capacitive light emitting device 1, between the cathode electrode and anode electrode of the capacitive light emitting device 1, and additionally turns off the drive element Q3, thereby returning the electric charges, which are accumulated in the reactor L2, to the capacitor C1 as the power source for regeneration.

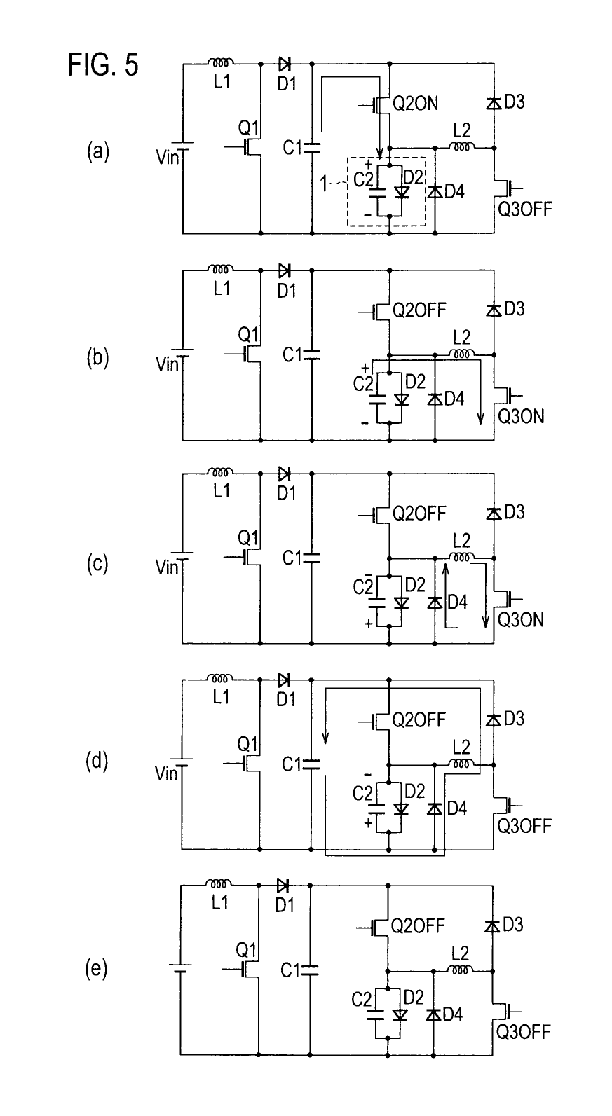

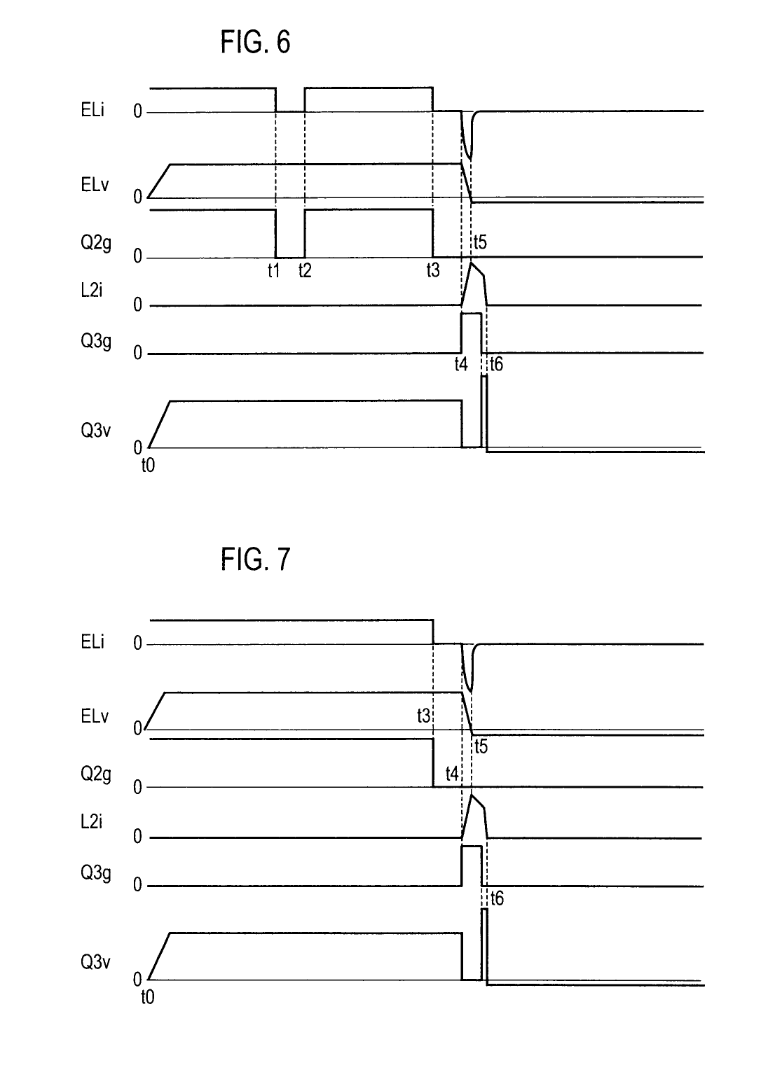

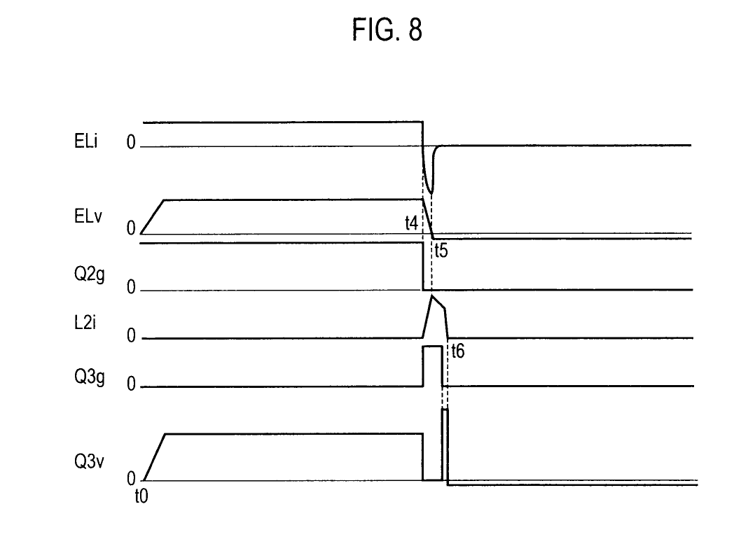

Next, descriptions will be provided for an operation which is performed by the thus-configured apparatus for driving a capacitive light emitting device according to Example 1. FIG. 5 is a diagram for explaining an operation which is performed by the apparatus for driving a capacitive light emitting device according to Example 1 in each mode. FIG. 6 is a timing chart showing an operation which is performed by each part in the apparatus for driving a capacitive light emitting device according to Example 1 in a case where: a dead time occurs; and regeneration is carried out for each two pulses. FIG. 7 is a timing chart showing an operation which is performed by each part in the apparatus for driving a capacitive light emitting device according to Example 1 in a case where a dead time occurs. FIG. 8 is a timing chart showing an operation which is performed by each part in the apparatus for driving a capacitive light emitting device according to Example 1 in a case where no dead time occurs.

In FIG. 6, an electric power is returned to the power supply for regeneration during a pulse from time t4 to time t6 out of two pulses (a pulse from time t2 to time t3 and the pulse from time t4 to time t6). In FIGS. 6 and 7, the dead time between a gate signal Q2g and a gate signal Q3g is a time length from time t3 to time t4. What makes the timing charts of FIGS. 6 and 7 different from that of FIG. 8 lies only in whether the dead time is present or absent. For this reason, descriptions will be provided for an operation which is performed by the apparatus for driving a capacitive light emitting device according to Example 1 in a case where no dead time is present by use of FIGS. 5 and 8.

Note that, in FIGS. 6 to 8, reference sign ELi denotes a current flowing in the capacitive light emitting device 1; ELv, a voltage between the two ends of the capacitive light emitting device 1; Q2g, a gate signal of the drive element Q2; L2i, a current flowing in the reactor L2; Q3g, a gate signal of the drive element Q3; and Q3v, a voltage between the source and drain of the drive element Q3.

First of all, let us assume that the voltage between the two ends of the capacitor C1 is at a predetermined voltage due to an operation of the boost chopper circuit. At time to, as shown in FIG. 5(a), when the drive element Q2 is turned on due to the gate signal Q2g while the drive element Q3 is off, the current Eli flows in a path from the capacitor C1, the drive element Q2, the capacitive light emitting device 1 to the capacitor C1. In other words, a forward bias is applied to the capacitive light emitting device 1, and the capacitive light emitting device 1 emits light.

Next, at time t4, as shown in FIG. 5(b), when the drive element Q2 is turned off due to the gate signal Q2g and simultaneously the drive element Q3 is turned on due to the gate signal Q3g, the capacitive light emitting device 1 and the reactor L2 are connected together in parallel. For this reason, the current L2i flows in the reactor L2 and drive element Q3 due to electric charges accumulated in the capacitor C2, which constitutes the parasitic capacitance of the capacitive light emitting device 1. As a result, energy is accumulated in the reactor L2.

Subsequently, at time t5, when the energy of the electric charges accumulated in the parasitic capacitance of the capacitive light emitting device 1 is reduced to zero, the current L2i flowing in the reactor L2 starts to decrease. Thereafter, as shown in FIG. 5(c), the reverse bias voltage ELv is applied to the capacitive light emitting device 1. Thus, the current L2i flows gradually diminishingly in a path from the reactor L2, the drive element Q3, the diode D4 to the reactor L2. On this occasion, the voltage ELv between the two ends of the capacitive light emitting device 1 is clamped by a threshold value of the diode 4. Hence, a voltage which is equal to or less than the reverse breakdown voltage of the capacitive light emitting device 1 is applied to the capacitive light emitting device 1.

Afterward, at time t6, as shown in FIG. 5(d), when the drive element Q3 is turned off due to the gate signal Q3g while the drive element Q2 remains off, a current flows in a path from the reactor L2, the diode D3, the capacitor C1, the diode D4 to the reactor L2. In other words, the energy accumulated in the reactor L2 is returned to the capacitor C1 on the power supply side for regeneration.

After that, as shown in FIG. 5(e), when the return of the energy to the capacitor C1 for regeneration is completed while the drive element Q2 and the drive element Q3 remain off and then the drive element Q2 is turned on again, the operation returns to the condition shown in FIG. 5(a).

As described above, in the case of the apparatus for driving a capacitive light emitting device according to Example 1, during a time period in which no voltage is applied between the cathode electrode and anode electrode of the capacitive light emitting device 1, the control circuit 10 turns on the drive element Q3, and thus accumulates electric charges, which are accumulated in the parasitic capacitance between the cathode electrode and anode electrode of the capacitive light emitting device 1, in the reactor L2. Furthermore, the control circuit 10 causes the diode D4 to apply the reverse voltage, which is equal to or less than the reverse breakdown voltage of the capacitive light emitting device 1, between the cathode electrode and anode electrode of the capacitive light emitting device 1, and additionally turns off the drive element Q3, thereby returning the electric charges, which are accumulated in the reactor L2, to the capacitor C1 as the power source for regeneration. For this reason, the apparatus for driving a capacitive light emitting device according to Example 1 is capable of efficiently using the electric charges which are charged in the parasitic capacitance and is accordingly capable of achieving the extension of the life of the capacitive light emitting device 1 and the enhancement of the power efficiency.

Moreover, in the case shown in FIG. 6, the control circuit 10 drives the capacitive light emitting device 1 with the gate signal Q2g of the drive element Q2, and turns on and off the drive element Q3 with the gate signal Q3g, one pulse of which the drive element Q3 outputs per output of every two pulses of the gate signal Q2g. For this reason, the control circuit 10 is capable of setting up one regeneration mode for each two light emitting pulses. Otherwise, the control circuit 10 may set up one regeneration mode for each three or more light emitting pulses.

Note that although, in the case of Example 1 shown in FIG. 3, one circuit is configured for the capacitive light emitting device 1, multiple circuits each shown in FIG. 3 may be provided for the purpose of making multiple capacitive light emitting devices 1 emit light. In this case, control of the on/off timings of the multiple drive elements Q2 makes it possible to control the timings of light emission of the capacitive light emitting elements 1, respectively.

### Example 2

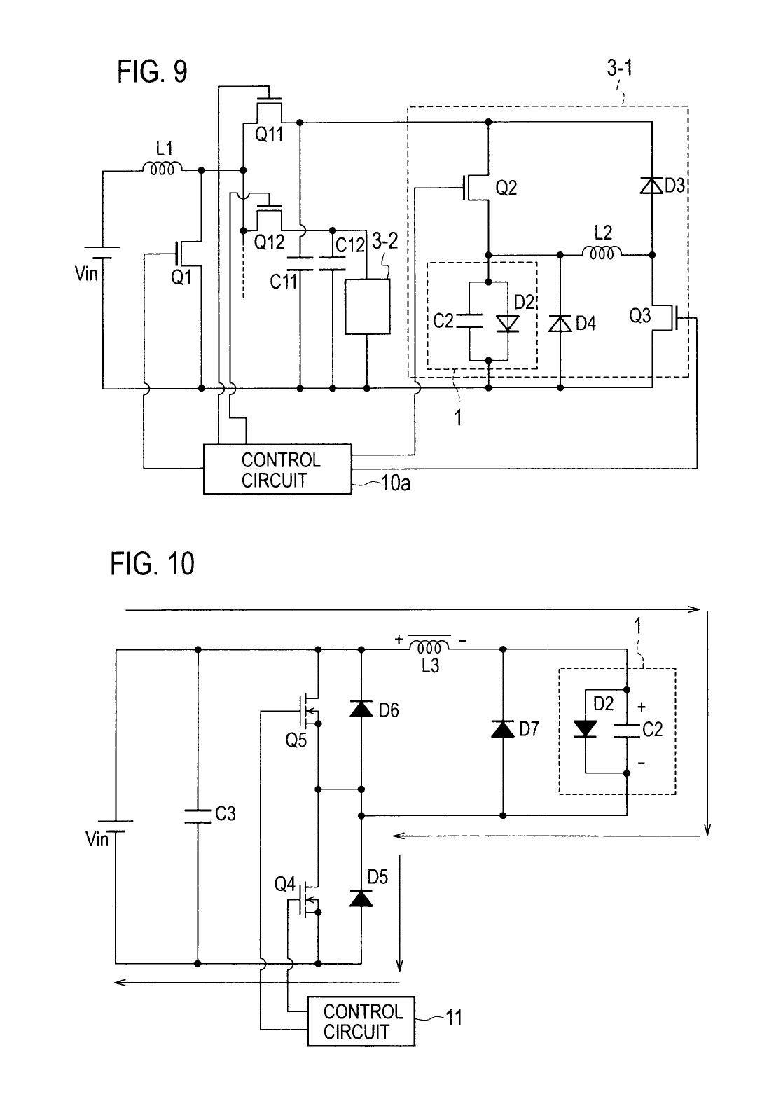

FIG. 9 is a circuit diagram of an apparatus for driving a capacitive light emitting device according to Example 2. Example 2 is characteristic in that multiple capacitive light emitting devices 1 are independently controlled with one power supply.

The series circuit including the reactor L1 and the drive element Q1 made of the MOSFET is connected to the two ends of the DC power supply Vin. N series circuits are connected between the drain and source of the drive element Q1 in a way that: a series circuit including a drive element Q11 made of a MOSFET and a part 3-1 for driving a capacitive light emitting device is connected between the drain and source of the drive element Q1; and a series circuit including a drive element Q12 made of a MOSFET and a part 3-2 for driving a capacitive light emitting device is connected between the drain and source of the drive element Q1.

Each of the parts 3-1 to 3-n for driving the respective capacitive light emitting devices is configured by including the drive elements Q2, Q3, the capacitive light emitting device 1, the diodes D3, D4 and the reactor L2.

Capacitors C11, C12 to C1n are connected between the drains of the drive elements Q11, Q12 to Q1n and the negative electrode of the DC power supply Vin, respectively. A control circuit 10a controls the on/off timings of the drive elements Q1 to Q3 and the drive elements Q11 to Q1n, respectively.

In the case of the thus-configured apparatus for driving a capacitive light emitting device according to Example 2, the control circuit 10a controls the on and off of each of the drive elements Q11 to Q1n and the drive element Q2. Accordingly, the apparatus for driving a capacitive light emitting device according to Example 2 is capable of controlling the light emission of the multiple capacitive light emitting devices 1.

### Example 3

FIG. 10 is a circuit diagram of an apparatus for driving a capacitive light emitting device according to Example 3. In FIG. 10, a capacitor C3 is connected to the two ends of the DC power supply Vin, and a series circuit including a drive element Q4 made of a MOSFET and a drive element Q5 made of a MOSFET is connected between the two ends of this capacitor C3. A diode D5 is connected between the drain and source of the drive element Q4, and a diode D6 is connected between the drain and source of the drive element Q5.

A series circuit including a reactor L3 and a diode D7 is connected to the two ends of the diode D6. The capacitive light emitting device 1 is connected to the two ends of the diode D7. A voltage reduced by a forward voltage drop of the diode D7 is equal to or less than the reverse breakdown voltage of the capacitive light emitting device 1.

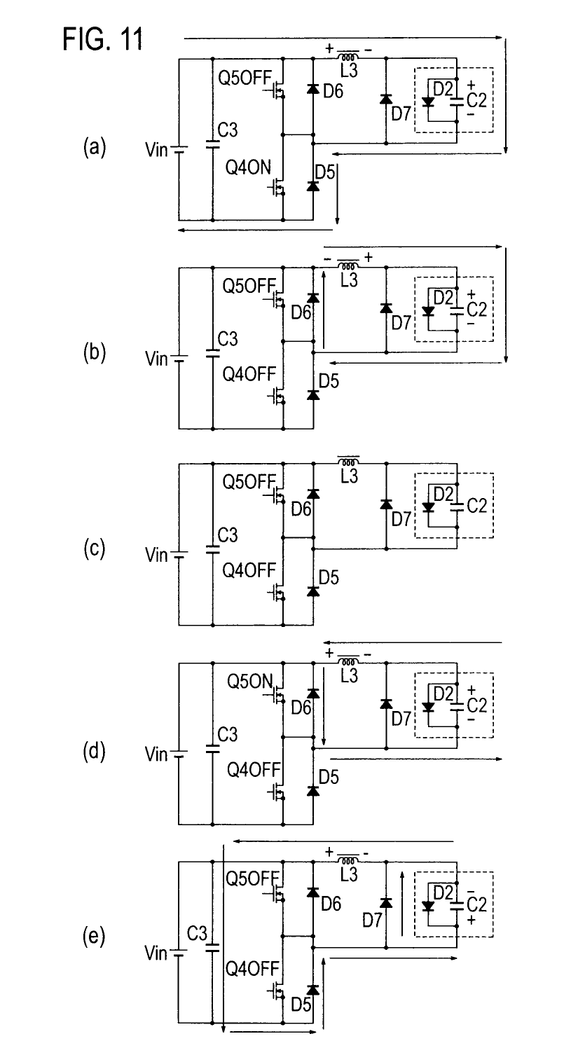

A control circuit 11 is connected to the gate of the drive element Q4 and the gate of the drive element Q5, and thus controls the light emission of the capacitive light emitting device 1 by controlling the on and off of the drive element Q4 with a PWM control signal. FIGS. 11(a) to 11(c). Note that the control circuit 11 turns on and off the drive elements Q4, Q5 alternately for regeneration and for applying the reverse voltage to the capacitive light emitting device 1. FIGS. 11(a) to 11(e).

Specifically, during a time period in which no voltage is applied between the cathode electrode and anode electrode of the capacitive light emitting device 1, the control circuit 11 turns on the drive element Q5, and thus accumulates electric charges, which are accumulated in the parasitic capacitance between the cathode electrode and anode electrode of the capacitive light emitting device 1, in the reactor L3. Subsequently, the control circuit 11 causes the diode D7 to apply a reverse voltage, which is equal to or less than the reverse breakdown voltage of the capacitive light emitting device 1, between the cathode electrode and anode electrode of the capacitive light emitting device 1, and additionally turns off the drive element Q5, thereby returning the electric charges, which are accumulated in the reactor L3, to the capacitor C3 as the power source for regeneration.

Next, descriptions will be provided for an operation which is performed by the thus-configured apparatus for driving a capacitive light emitting device according to Example 3 by referring to FIG. 11.

First of all, as shown in FIG. 11(a), when the drive element Q4 is turned on while the drive element Q5 is off, an electric current flows in a path from the DC power supply Vin, the reactor L3, the capacitive light emitting device 1, the drive element Q4 to the DC power supply Vin due to the DC power supply Vin. In other words, the forward bias is applied to the capacitive light emitting device 1, and the capacitive light emitting device 1 emits light.

Next, as shown in FIG. 11(b), when the drive element Q4 is turned off, the polarity of the reactor L3 is reversed, and energy accumulated in the reactor L3 is discharged. Thus, an electric current flows in a path from the reactor L3, the capacitive light emitting device 1, the drive element Q5 to the reactor L3. In other words, the capacitive light emitting device 1 emits light due to the energy of the reactor L3.

Next, as shown in FIG. 11(c), the reactor L3 completes discharging the energy. Thereafter, as shown in FIG. 11(d), the polarity of the reactor L3 is reversed, and an electric current accordingly flows in a path from the capacitive light emitting device 1, the reactor L3, the drive element Q5 to the capacitive light emitting device 1 due to electric charges which are accumulated in the capacitor C2 that is the parasitic capacitance of the capacitive light emitting device 1. Consequently, energy is accumulated in the reactor L3.

Subsequently, as shown in FIG. 11(e), when the drive element Q5 is turned off, the energy accumulated in the reactor L3 is returned to the capacitor C3 for regeneration. In other words, an electric current flows in a path from the reactor L3, the capacitor C3, the diode D5, the capacitive light emitting device 1 to the reactor L3. On this occasion, the voltage between the two ends of the capacitive light emitting device 1 is clamped by a forward voltage of the diode D7. Accordingly, a voltage which is equal to or less than the reverse breakdown voltage of the capacitive light emitting device 1 is applied to the capacitive light emitting device 1.

As described above, the apparatus for driving a capacitive light emitting device according to Example 3 operates in a manner similar to that in which the apparatus for driving a capacitive light emitting device accord to Example 1 operates, and brings about the same effects as does the apparatus for driving a capacitive light emitting device according to Example 1.

### (Structure of Capacitive Light Emitting Device)

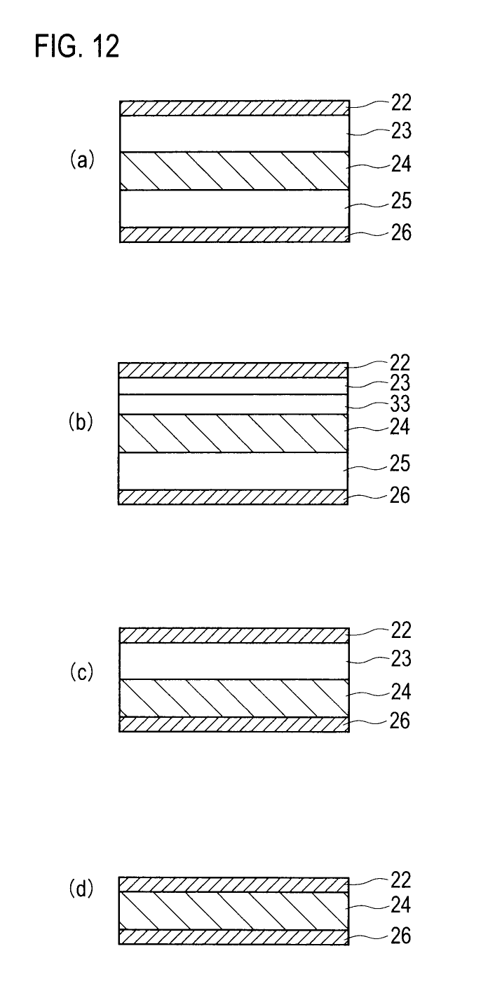

Next, descriptions will be provided for a basic structure for the capacitive light emitting devices 1 according to Examples 1 to 3 by use of FIG. 12. The capacitive light emitting devices each include an electrode which covers all or part of the front surface of the device. In a case where a transparent electrode is used, the transparent electrode covers all or part of the front surface of the device. In a case where a metal electrode is used, the metal electrode covers part of the front surface of the device in a way that light is outputted toward the front side.

In a capacitive light emitting device shown in FIG. 12 (a), a hole injection layer 23 is laminated to a transparent electrode 22 for a positive electrode (+) (corresponding to the anode electrode according to the present invention). The transparent electrode 22 is made of indium tin oxide or the like. The hole injection layer 23 is made of an organic substance, or an inorganic material or substance which has the same or equivalent performance as does the organic substance. The hole injection layer 23 and an electron injection layer 25 may change their places.

As an organic EL layer, a light emitting layer 24 made of an organic substance is laminated to the hole injection layer 23. The electron injection layer 25 is laminated to the light emitting layer 24. The electron injection layer 25 is made of an organic substance, or an inorganic material which has the same or equivalent performance as does the organic substance. An electrode 26 for a negative electrode (−) (corresponding to the cathode electrode according to the present invention) is laminated to the electron injection layer 25.

Note that, although not illustrated, multiple transparent electrodes 22 may be installed together, and multiple electrodes 26 may be installed together. The electrode 26 is made of a material which has a high reflectance in a visible light range. The electrode 26 additionally plays a function of outputting light through the transparent electrode.

Alternatively, light may be outputted through both the anode and the cathode by using a transparent electrode as the electrode 26 as well. Furthermore, a capacitive light emitting device shown in FIG. 12(b) is one obtained by providing the structure of the capacitive light emitting device shown in FIG. 12(a) with a hole transportation layer 33 placed between the hole injection layer 23 and the light emitting layer 24.

Moreover, a capacitive light emitting device shown in FIG. 12(c) is one obtained by removing the electron injection layer 25 from the structure of the capacitive light emitting device shown in FIG. 12(a). A capacitive light emitting device shown in FIG. 12(d) is one obtained by removing the hole injection layer 23 from the structure of the capacitive light emitting device shown in FIG. 12(c). The capacitive light emitting devices having such structures may be used.

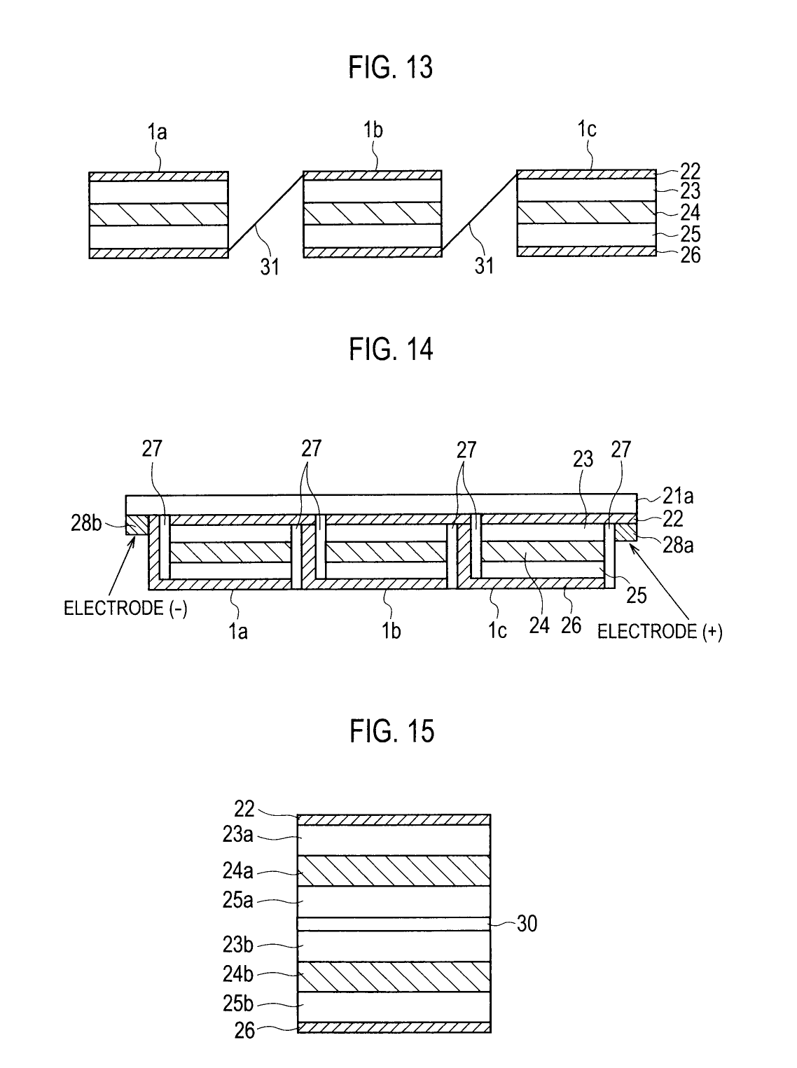

Alternatively, a first configuration example where, as shown in FIG. 13, three capacitive light emitting devices 1a to 1c each having the configuration as shown in FIG. 12 as the capacitive light emitting device are connected together in series may be used. In the case of the first configuration example shown in FIG. 13, the electrode 26 of the capacitive light emitting device 1a and the transparent electrode 22 of the capacitive light emitting device 1b are connected together with a wire 31 or an electrode interconnection, while the electrode 26 of the capacitive light emitting device 1b and the transparent electrode 22 of the capacitive light emitting device 1c are connected together with another wire 31 or another electrode interconnection. For this reason, a higher brightness can be obtained.

Otherwise, a second configuration example where, as shown in FIG. 14, the three capacitive light emitting devices 1a to 1c are connected together in series may be used. In the case of the second configuration example shown in FIG. 14, three transparent electrodes 22 are laminated to a transparent substrate 21a. Furthermore, the hole injection layers 23, the light emitting layers 24, the electron injection layers 25 and the electrodes 26 are sequentially laminated to the transparent electrodes 22, respectively. The transparent electrodes 22 are separated by separators 27.

Note that, although the second configuration example shown in FIG. 14 is provided with the transparent substrate 21a, the second configuration example may be provided with no transparent substrate 21a.

An electrode (+) 28a is connected to the transparent electrode 22 of the capacitive light emitting device 1c, and the electrode 26 of the capacitive light emitting device 1c is connected to the transparent electrode 22 of the capacitive light emitting device 1b. The electrode 26 of the capacitive light emitting device 1b is connected to the transparent electrode 22 of the capacitive light emitting device 1a, and the electrode 26 of the capacitive light emitting device 1a is connected to an electrode (−) 28b. The above configuration makes the three capacitive light emitting devices 1a to 1c connected together in series.

A higher brightness can be obtained from such a second configuration example shown in FIG. 14 as in the case of the first configuration example shown in FIG. 13.

FIG. 15 is a diagram of a structure of a capacitive light emitting device including multiple light emitting layers. In the capacitive light emitting device shown in FIG. 15, a hole injection layer 23a is laminated to the transparent electrode 22; a light emitting layer 24a is laminated to the hole injection layer 23a; and an electron injection layer 25a is laminated to the light emitting layer 24a.

A separation layer 30 made of a light-transmitting thin metal layer or a light-transmitting thin dielectric layer is laminated to the electron injection layer 25a. A hole injection layer 23b is laminated to the separation layer 30. A light emitting layer 24b is laminated to the hole injection layer 23b. An electron injection layer 25b is laminated to the light emitting layer 24b. The electrode 26 is laminated to the electron injection layer 25b.

Because, as described above, the light emitting layers 24a, 24b are installed in the capacitive light emitting device and are connected together in series, a higher brightness can be obtained.

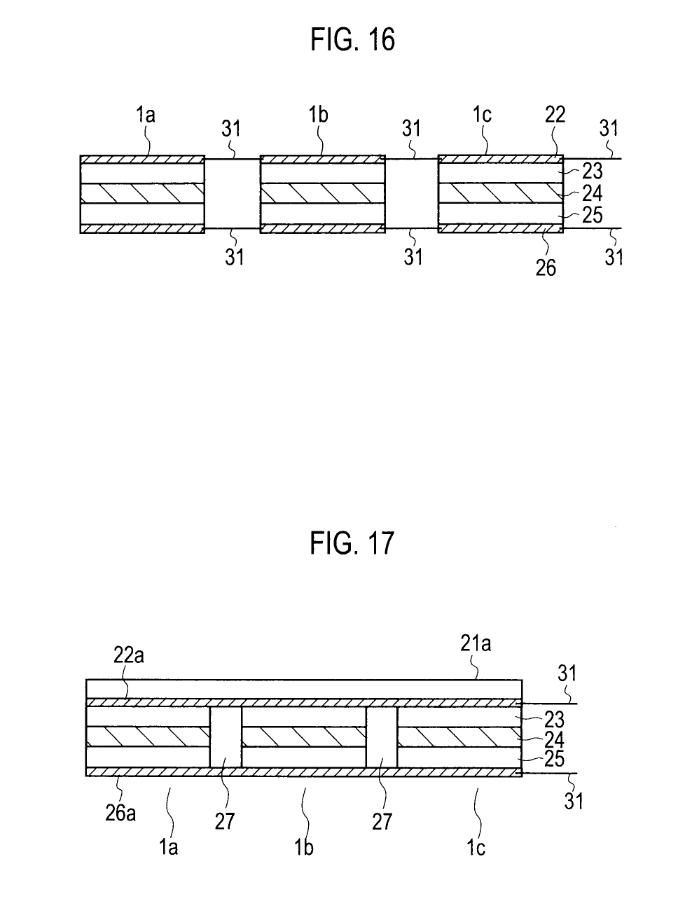

FIG. 16 is a diagram showing the first configuration example where the multiple capacitive light emitting devices are connected together in parallel instead. In the first configuration example shown in FIG. 16, the transparent electrodes 22 of the respective capacitive light emitting devices 1a, 1b, 1c each having a configuration which is identical to the configuration shown in FIG. 12 are commonly connected together with an electrode interconnection or wire 31. The electrodes 26 of the respective capacitive light emitting devices 1a, 1b, 1c are commonly connected together with a wire 31. In other words, the capacitive light emitting devices 1a, 1b, 1c are connected together in parallel. For this reason, the first configuration example shown in FIG. 16 can increase the light emitting area of the capacitive light emitting devices.

FIG. 17 is a diagram showing the second configuration example where the multiple capacitive light emitting devices are connected together in parallel instead. In the second configuration example shown in FIG. 17, a transparent electrode 22a is laminated to the transparent substrate 21a, and the three hole injection layers 23 are laminated to the transparent electrode 22a. The light emitting layers 24 and the electron injection layers 25 are sequentially laminated to the hole injection layers 23, respectively. An electrode layer 26a is laminated to each of the three electron injection layers 25. Thereby, the three capacitive light emitting devices 1a to 1c are formed. The three capacitive light emitting devices 1a to 1c are separated by separators 27.

Such a second configuration example shown in FIG. 17 can increase the light emitting area of the capacitive light emitting devices, because the three capacitive light emitting devices 1a to 1c are connected together in parallel.

Note that, although the second configuration example shown in FIG. 17 is provided with the transparent substrate 21a, the second configuration example may be provided with no transparent substrate 21a.

The present invention makes it possible to efficiently use electric charges stored in a parasite capacitance, extend the life of the capacitive light emitting device(s), and reduce the power consumption.

The present invention makes it possible to obtain a higher brightness, because the multiple capacitive light emitting devices are connected together in series or in parallel.

The present invention makes it possible to obtain a higher brightness, because a single capacitive light emitting device includes multiple light emitting layers.

The control circuit according to the present invention turns on and off a drive element with a second pulse signal, one pulse of which is outputted per output of every two or more pulses of a first pulse signal of another drive element. For this reason, the control circuit is capable of setting up one regeneration mode for each multiple light emitting pulses, and is accordingly capable of adjusting the balance between the life and the reduction in power consumption.

### INDUSTRIAL APPLICABILITY

The present invention can be applied to organic EL devices and other light emitting devices.

1. An apparatus for driving a capacitive light emitting device, comprising:
a capacitive light emitting device placed between a cathode electrode and an anode electrode opposite to each other on a light-transmitting substrate;
a power supply connected to the capacitive light emitting device;
drive means for driving the capacitive light emitting device by applying a DC voltage of the power supply between the cathode electrode and the anode electrode; and
regeneration means for returning an electric charge to the power supply for regeneration, the electric charge being accumulated in a parasitic capacitance of the capacitive light emitting device while the capacitive light emitting device is driven.

2. The apparatus for driving a capacitive light emitting device according to claim 1, wherein:
the capacitive light emitting device is provided in plurality; and
the plurality of capacitive light emitting devices are connected together in series or in parallel.

3. The apparatus for driving a capacitive light emitting device according to claim 1, wherein:
the capacitive light emitting device includes a plurality of light emitting layers made of organic substances placed between the cathode electrode and the anode electrode, the organic substances are laminated together by use of a separation layer having an electrical conductivity and a light transmitting property; and
each or all of the plurality of separated light emitting layers emit light.

4. An apparatus for driving a capacitive light emitting device, comprising:
a capacitive light emitting device placed between a cathode electrode and an anode electrode opposite to each other on a light-transmitting substrate;
a power supply connected to the capacitive light emitting device;
drive means for driving the capacitive light emitting device by applying a DC voltage of the power supply between the cathode electrode and the anode electrode; and
regeneration means being connected to the capacitive light emitting element, and including a reactor, a rectifier and a drive element,
wherein the regeneration means turns on the drive element to accumulate in the reactor an electric charge which is accumulated in a parasitic capacitance of the capacitive light emitting device while the capacitive light emitting device is driven; thereafter causes the rectifier to apply a reverse voltage, which is equal to or less than a reverse breakdown voltage of the capacitive light emitting device, to the capacitive light emitting device; and turns off the drive element to return the electric charge, which is accumulated in the reactor, to the power supply for regeneration.

5. The apparatus for driving a capacitive light emitting device according to claim 4, wherein:
the light emitting device is provided in plurality; and
the plurality of capacitive light emitting devices are connected together in series or in parallel.

6. The apparatus for driving a capacitive light emitting device according to claim 4, wherein:
the capacitive light emitting device includes a plurality of light emitting layers made of organic substances placed between the cathode electrode and the anode electrode, the organic substances are laminated together by use of a separation layer having an electrical conductivity and a light transmitting property; and
each or all of the plurality of separated light emitting layers emit light.

7. The apparatus for driving a capacitive light emitting device according to claim 4, characterized in that:
the drive means drives the capacitive light emitting element with a first pulse signal; and
the control circuit turns on and off the drive element with a second pulse signal, one pulse of the second pulse signal being outputted per output of every two or more pulses of the first pulse signal.
